(19) United States
(12) Patent Application Publication
(10) Pub. No.: US 2025/0308860 A1
(43) Pub. Date: Oct. 2, 2025

(54) CONTROLLING ETCH EDGE EFFECTS

(71) Applicant: Tokyo Electron Limited, Tokyo (JP)

(72) Inventors: Matthew Charles Gwinn, Winchendon, MA (US); Steven Nelson, Chaska, MN (US); Stephen Loper, Chaska, MN (US); Randolph Wagner, Richardson, TX (US)

(21) Appl. No.: 18/620,762

(22) Filed: Mar. 28, 2024

(51) Int. Cl. H01J 37/32; H01L 21/3065; H01L 21/67

(52) U.S. Cl. CPC H01J 37/32651; H01J 37/32733; H01L 21/3065; H01L 21/67069; H01L 21/67259; H01J 2237/20292; H01J 2237/24578; H01J 2237/334

(57) ABSTRACT

A method for controlling an etch edge effect in a partial plasma etch process includes loading a substrate in a processing chamber with a backside shield disposed around the substrate, and configuring the backside shield according to a calibration specific to one or more process recipes. The method further includes generating, based on the process recipe, a plasma at a plasma source, and directing, based on the process recipe, the plasma into the processing chamber and towards outer surfaces of the substrate and the backside shield using a nozzle. And the method further includes processing the substrate by exposing the substrate and the backside shield to the plasma based on the one or more process recipes.

### TECHNICAL FIELD

The present invention relates generally to the field of plasma processing and more specifically, to systems and methods of controlling etch edge effects.

### BACKGROUND

Plasma processing has become an integral part of modern semiconductor fabrication, offering unmatched precision and control in etching and patterning various materials. In partial plasma etch (PPE) applications, plasma is used to selectively remove or modify materials on a semiconductor substrate to create intricate patterns and structures. However, as semiconductor technology progresses from one generation to the next, the limitations of traditional plasma processing techniques have become increasingly evident.

One of the major challenges faced in PPE applications is the etch edge effect, which refers to the non-uniformity and damage that occurs at the edges of a substrate. This phenomenon is caused by several factors, including ion bombardment, sidewall passivation, and scattering of charged particles within the plasma. The etch edge effect can lead to a loss of device performance, reduced yield, and increased defect density, ultimately affecting the reliability and functionality of semiconductor devices.

Various attempts have been made to address the etch edge effect. Existing methods typically involve adjusting process parameters, such as gas composition, pressure, power, and temperature, to minimize the non-uniformity at the edges of substrates.

### SUMMARY

A method for controlling an etch edge effect in a partial plasma etch process includes loading a substrate in a processing chamber with a backside shield disposed around the substrate, and configuring the backside shield according to a calibration specific to one or more process recipes. The method further includes generating, based on the process recipe, a plasma at a plasma source, and directing, based on the process recipe, the plasma into the processing chamber and towards outer surfaces of the substrate and the backside shield using a nozzle. And the method further includes processing the substrate by exposing the substrate and the backside shield to the plasma based on the one or more process recipes.

A system includes a measurement device, a plasma source, a processing chamber, the plasma source being coupled to the processing chamber through a nozzle, the nozzle configured to emit a processing beam into the processing chamber, and a substrate holder disposed in the processing chamber and being configured to support a substrate. The system further includes a backside shield disposed in the processing chamber and being configured to laterally surround an edge of the substrate, a stage supporting the substrate holder and being disposed in the processing chamber. And the system further includes a controller coupled to the stage, and a memory storing instructions to be executed by the controller. The instructions when executed cause the controller to configure the backside shield according to a calibration specific to one or more process recipes, generate, based on the one or more process recipes, a plasma at a plasma source, direct, based on the one or more process recipes, the plasma into the processing chamber and towards outer surfaces of the substrate and the backside shield using the nozzle, and process the substrate according to the one or more process recipes by scanning the substrate with the processing beam to expose different regions of the substrate to the processing beam.

And a calibration method includes loading a first substrate in a processing chamber with a backside shield disposed around the first substrate, and generating, based on one or more process recipes, a plasma at a plasma source. The calibration method further includes directing, based on the one or more process recipes, the plasma into the processing chamber and towards outer surfaces of the first substrate and the backside shield using a nozzle, and processing the first substrate, based on the one or more process recipes, by exposing the first substrate and the backside shield to the plasma to form a processed first substrate. And the calibration method further includes scanning an edge of the processed first substrate using a measurement device, determining a process amount of the edge based on the scanning, and determining a configuration of the backside shield for the one or more process recipes based on the process amount.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A is a schematic diagram of a system for processing a substrate for PPE applications including a backside shield for controlling the etch edge effect and a measurement device for monitoring the etch edge effect;

FIG. 1B is an aerial view of a substrate with a backside shield in an embodiment where the backside shield is a solid ring mounted around the substrate;

FIG. 1C is an aerial view of the substrate with the backside shield in an embodiment where the backside shield comprises a plurality of arcs that when they are mounted together form a concentric ring around the substrate;

FIG. 2 is a plot of the poly etch amount at different radial distances from the center of the substrate in various embodiments with backside shields and without backside shields;

FIG. 3A is a diagram of an aerial view of a substrate with a non-porous backside shield;

FIG. 3B is a diagram of a cross-sectional view of a substrate with a non-porous backside shield illustrating the behavior of particles of the available chemistry of a processing beam;

FIG. 4A is a diagram of an aerial view of a substrate with a porous backside shield;

FIG. 4B is a diagram of a cross-sectional view of a substrate with a porous backside shield illustrating the behavior of particles of the available chemistry of a processing beam;

FIG. 5A is a diagram of a cross-sectional view of a substrate with an angled backside shield illustrating the behavior of particles of the available chemistry of a processing beam;

FIG. 5B is a diagram of a cross-sectional view of a substrate with a sloped backside shield illustrating the behavior of particles of the available chemistry of a processing beam;

FIG. 6 is a diagram of a cross-sectional view of a substrate with a recessed backside shield illustrating the behavior of particles of the available chemistry of a processing beam;

FIG. 7 is a flowchart of an embodiment method of processing a substrate with a backside shield for PPE application while monitoring the process to update and change configuration settings of the backside shield based on the monitoring; and

FIG. 8 is a flowchart of a method for calibrating the system of this disclosure for a particular process recipe to control the etch edge effect in an embodiment.

### DETAILED DESCRIPTION OF ILLUSTRATIVE EMBODIMENTS

A partial plasma etch (PPE) process is an etching process that removes only a part of the material. The amount of material removed by the etch process is controlled by varying a scan speed of the PPE process. For example, the scan speed may be reduced to cause a larger amount of material to be etched, or the scan speed may be increased to cause a smaller amount of material to be etched. This control may be useful in a number of applications, where only a specific depth of material is specified to be removed, while leaving the underlying material intact. Once the specified amount of material has been removed, the process is stopped, leaving a precisely etched surface. This is key in fabricating complex microelectronics where structures of varying depths are specified for the same semiconductor wafer. In effect, such partial plasma etch processes may be used as burnishing processes to improve surface roughness, improve dimensional control, and provide a planarized surface. Although embodiments of this application will be described using a plasma process, they are also applicable for other types of processes such as using ion beams such as gas cluster ion beam (GCIB) processing.

A difficulty frequently encountered in semiconductor manufacturing using partial plasma etch (PPE) applications is the etch edge effect. When a substrate is subject to PPE applications and encounters the etch edge effect, the etch edge effect may cause variations in feature dimensions and profile shapes on the substrate at the edge of the substrate. This physical process often leads to inconsistencies in plasma etching results, which can significantly hamper the efficiency and reliability of electronic devices produced. Therefore, reducing the etch edge effect and harmonizing the etching rate across the whole substrate surface can improve device performance and fabrication efficiency in the semiconductor manufacturing industry.

One prior approach in addressing the edge etch effect involves manipulating plasma uniformity, but this method often proves inadequate and unsatisfactory as it does not entirely eliminate discrepancies in etching performance towards the substrate edge. By contrast, the embodiment systems and methods of this disclosure use a backside shield mounted around the substrate as a more effective method to control the etch edge effect. The various embodiments of backside shields of this disclosure, with their unique design, robust construction, and strategic positioning, can effectively contribute to optimizing and controlling the etching process and minimizing unwanted inconsistencies. In one particular aspect, this is conducted through the strategic implementation of a backside shield mounted around a substrate to control the etch edge effect.

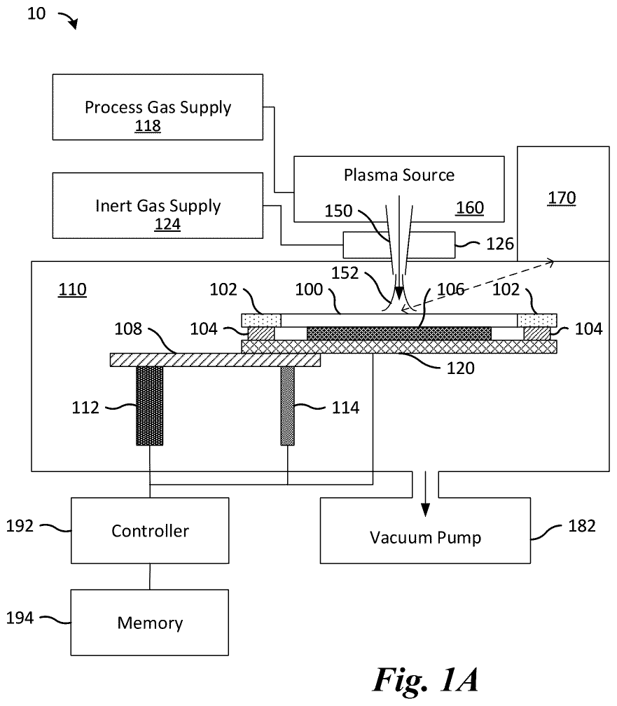

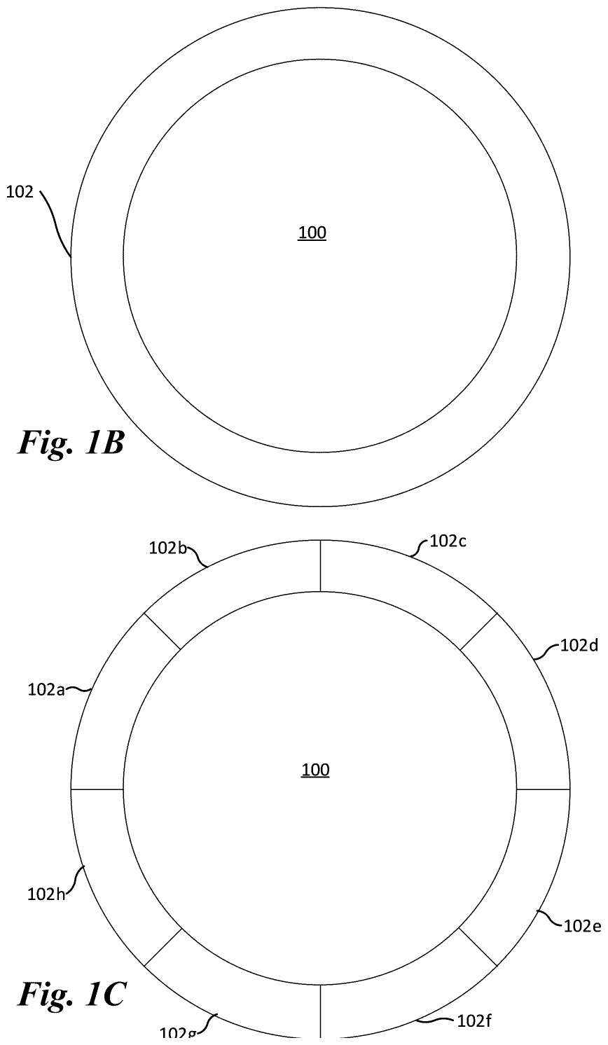

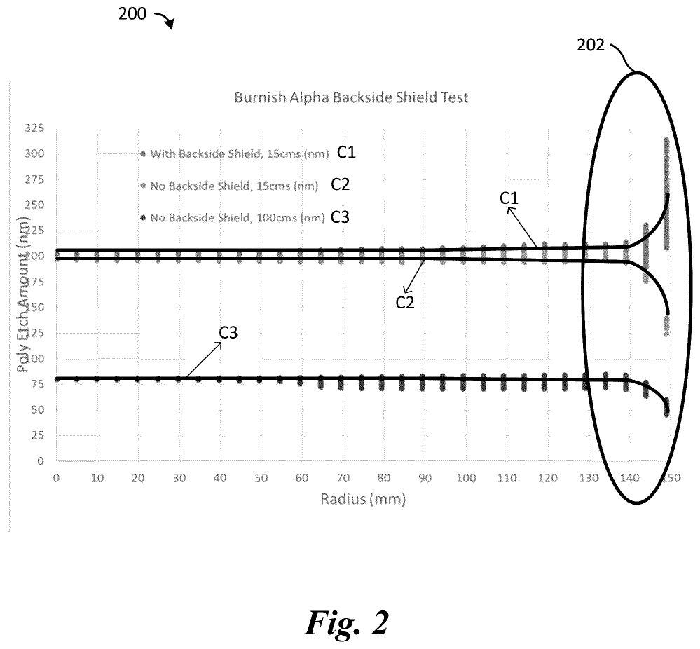

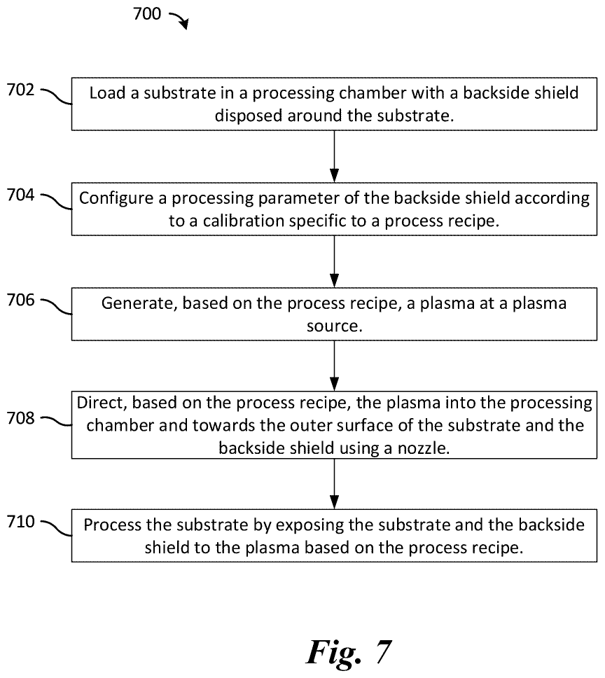

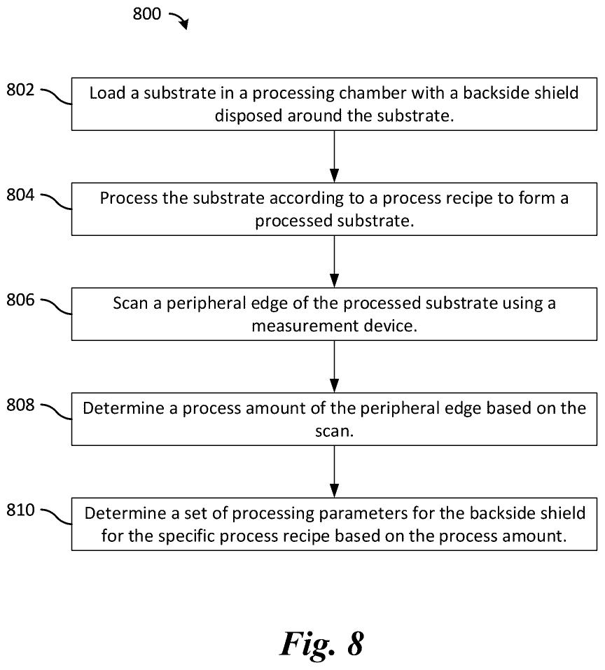

Embodiments provided below describe various systems and methods for controlling etch edge effect in PPE applications, and in particular, methods using a backside shield mounted around a substrate. The following description describes the embodiments. A system for processing a substrate for PPE applications including a backside shield and measurement device for monitoring the etch edge effect is illustrated in FIG. 1A. An aerial view of a substrate and a backside shield mounted to the substrate is illustrated in FIG. 1B in an embodiment where the backside shield is a single ring-like disk. FIG. 1C is an aerial view of the substrate and the backside shield mounted to the substrate in an embodiment where the backside shield is a plurality of arcs forming a ring when disposed around, e.g., concentrically, the substrate together. A representative plot of an etch amount of a polysilicon film at different radial distances from the center of the substrate is illustrated in FIG. 2 for various embodiments using a backside shield and not using a backside shield. FIGS. 3A-3B, 4A-4B, 5A-5B, and 6 illustrate various embodiments of the backside shield mounted around the substrate. FIG. 7 is a flowchart of an embodiment method of processing a substrate with a backside shield for PPE application while monitoring the process to update and change configuration settings of the backside shield based on the monitoring. And an embodiment method of calibrating the system with a backside shield for a particular process recipe is illustrated as the flowchart of FIG. 8.

FIG. 1A illustrates a schematic diagram of a cross-sectional view of a plasma processing system 10 in accordance with an embodiment of this disclosure.

Depending upon the implementation, the plasma processing system 10 may be a capacitively coupled plasma (CCP) processing system, inductively coupled plasma (ICP) processing system, microwave-generated plasma system, or the like. The example plasma processing system 10 is described subsequently for use in the context of etching operations. However, aspects of the embodiments described herein may be used for other plasma operations including ashing, deposition, cleaning, plasma polymerization, plasma-enhanced chemical vapor deposition (PECVD), plasma-enhanced atomic layer deposition (PEALD) and so forth. Plasma processing can be executed within a processing chamber 110, which can be a vacuum chamber made of a metal such as aluminum, stainless steel, or the like.

The plasma processing system 10 includes a measurement device 170 which may be used to scan a substrate 100 during processing or after processing. Depending on the implementation, either the substrate may be moved or a processing nozzle 150 delivering a plasma to the substrate may be moved during the processing.

Referring to FIG. 1A, in one embodiment, the plasma processing system 10 comprises the measurement device 170 coupled to a plasma source 160 coupled to a processing chamber 110 through a processing nozzle 150. The processing nozzle 150 is configured to localize a spot on the substrate 100 for processing. For example, the processing nozzle 150 may focus a processing beam (such as an etch beam) for processing of the substrate 100. The processing chamber 110 houses a pendulum arm 108, a stage 120, a shield mount 104, a substrate holder 106, a backside shield 102, and the substrate 100. A vacuum pump 182 is coupled to the processing chamber 110.

Still referring to FIG. 1A, a controller 192 is operationally coupled to a pivot point access 114 and an arc axis 112, and is configured to control the simultaneous movement of a first and second rotary drive to enable arc motion of the stage 120 to be able to expose the entire surface of the substrate 100 to the plasma source 160 and the measurement device 170. The controller 192 is further operationally coupled to the stage 120 to control a set of parameters to adjust the shield mount 104 and the substrate holder 106, which may be configured to control the etch edge effect on the substrate 100. The controller 192 may also be coupled to a memory 194 storing instructions for controlling the etch edge effect, and instructions when executed to process the substrate 100 according to the method of controlling the etch edge effect of this disclosure.

In various embodiments, the substrate 100 may be any material suitable for processing via the plasma processing system 10 of this disclosure, such as silicon. In similar embodiments, the material of the backside shield 102 may be chosen to control the etch edge effect on the edge of the substrate 100 based on the material of the substrate 100. By varying the material of the backside shield 102, changing the angle of the backside shield 102 relative to the substrate 100, and changing a height offset between the substrate 100 and the backside shield 102, the etch edge effect may be controlled, which is a benefit of the system and method of this disclosure. Controlling the etch edge effect using the system and method of this disclosure can ameliorate the edge etch effect (increase uniformity) without regard for throughput, and without overcomplicating the processing procedure, which are key benefits of the system and method of this disclosure, as well.

In an embodiment, the shield mount 104 may be a plurality of arcs of shield mounts that may be tilted and raised or lowered. In other embodiments, the shield mount 104 may be a single disk which may be tilted and raised or lowered relative to the substrate holder 106. The stage 120 is coupled to the shield mount 104 and the substrate holder 106, and is coupled to the controller 192 to enable the controller 192 to configure the processing parameters of the shield mount 104 relative to the substrate holder 106 to angle, or control a height offset of the shield mount 104 relative to the substrate holder 106. In an embodiment, the substrate holder 106 may be a chuck capable of increasing or decreasing a recess distance (or height distance) relative to the stage 120 to form a difference in height between the substrate 100 and the backside shield 102.

The controller 192 may be any device capable of implementing the instructions stored in the memory 194 for controlling and operating the plasma processing system 10 to implement the method of controlling the etch edge effect of this disclosure. The memory 194 may be any device suitable for storing instructions to be executed by the controller 192. Further, the memory 194 may be any device suitable for storing the measurement device 170 data (e.g., etch amounts, deposition amounts, surface smoothness, etcetera), and storing the instructions, such as RAM, ROM, PROM, EPROM, EEPROM, hard disk, or any other information processing device with which the controller 192 communicates, such as a server or computer.

In various embodiments, the plasma source 160 may be a plasma generation chamber, for example, a remote plasma generation chamber in an embodiment. The plasma source 160 may be coupled to an energy source, for example, a microwave generator that generates electromagnetic waves (microwaves), which are then distributed to the plasma source 160 in which plasma is generated. In other embodiments, the source of the electromagnetic waves may have a frequency that is in a range from the 10's of MHz (e.g., Radio-Frequency (RF)) to 1-30 GHz (microwave). The plasma source 160 is disposed above the processing chamber 110, and may comprise a plasma cavity and a plasma element that is used to produce plasma in the plasma cavity. In an embodiment, the plasma source 160 may be a remote plasma source that is disposed in a different location, with the plasma being directed to a surface to be etched after being generated. The plasma element may produce a mixture of plasma and radicals which then flows into the processing chamber 110 through the processing nozzle 150. The plasma is therefore generated outside of the processing chamber 110 and then introduced into the processing chamber 110 using a gas flow.

The measurement device 170 may be any device capable of imaging/measuring an etch depth on the surface of the substrate 100 and monitoring the etch edge effect at the edge of the substrate 100. For example, the measurement device 170 may be an optical device such as a scaterrometer, a CCD/CMOS image sensing device, infrared interferometer, electron microscopy, and others. The measurement device 170 may be capable of, after image processing, determining the processing amount (such as etch amount) at the edge of the substrate 100 from imaging the surface. In an embodiment, by moving the substrate 100 relative to the measurement device 170, the measurement device 170 may scan the edge of the substrate 100 during or after processing with the plasma source 160. The scan of the edge of the substrate 100 may be processed to simultaneously adjust processing parameters, such as a height or angle tilt of the shield mount 104, in order to ameliorate and control the etch edge effect. In other embodiments, the scan of the edge of the substrate 100 may be processed to adjust processing parameters iteratively (after the processing has finished) to change the processing of the next substrate in response to the scan.

A process gas is introduced into the plasma cavity of the plasma source 160, where it is ionized and excited by the plasma. This gas may be a mixture of one or more reactive gases, such as oxygen, nitrogen, hydrogen, fluorine, or the like, depending on the specific process being performed. In an embodiment, the process gas may be a fluorine-rich precursor, such as NF₃, SF₆, or the like. The process gas is supplied using a process gas supply 118, and is introduced into the plasma cavity through a gas inlet. The process gas may be mixed with a carrier gas, such as argon or helium, to ensure uniform distribution and stable plasma operation. The gas mixture is then energized by the plasma, which dissociates the gas molecules into reactive species such as radicals, ions, or excited molecules.

The plasma and radicals generated in the plasma source 160 then flow into the processing chamber 110 through the processing nozzle 150 and exit over the substrate 100. The plasma and radicals are directed towards the top surface of the substrate 100 in the form of a plasma plume 152 (also referred to as a plasma stream) at the exit of the processing nozzle 150. The plasma plume 152 comprises a narrow column or stream of plasma and radicals.

The plasma processing system 10 may comprise a gas shroud 126 that may be used to control a lateral width of the plasma plume 152, and allow for the focusing of the plasma plume 152 on a smaller area of the substrate 100 surface (e.g., by reducing a lateral width of the plasma plume 152). The processing nozzle 150 is disposed to be fitted such that the gas shroud 126 surrounds vertical sidewalls of the processing nozzle 150, and a fit between the processing nozzle 150 and a top surface of the gas shroud 126 is sealed to gas. The gas shroud 126 comprises a gas plenum that is designed to create an inward flow of inert gas at high speeds. The flow of inert gas is created from an inert gas supplied to the gas plenum by an inert gas supply 124. The inert gas may comprise argon, nitrogen, or the like.

The vacuum pump 182 is connected to the processing chamber 110 through a gas outlet, and the vacuum pump 182 helps to maintain a desired pressure within the processing chamber 110.

FIGS. 1B-1C illustrate different embodiments for surrounding the substrate 100 with the backside shield 102. An aerial view of an embodiment of the backside shield 102 disposed around the substrate 100 is illustrated in FIG. 1B. The embodiment of the backside shield 102 in FIG. 1B is a single disk around the substrate, but other embodiments may be used. For example, FIG. 1C illustrates an aerial view of an embodiment where the backside shield 102 of FIG. 1B has been separated into a plurality of backside shield arcs 102a-102h. In various other embodiments, the backside shield arcs 102a-102h may be separated into even more arcs surrounding the substrate 100.

When the backside shield 102 is used, the abundance of available chemistry for processing increases as a processing beam (or etch beam) scans off the edge of the substrate 100. This is a result of the available chemistry (such as etching gas) not being consumed by the backside shield 102, and instead reflecting back to the substrate 100 after scattering, which causes an increase in the amount of processing at the edge of the substrate 100. For example, in an embodiment where the processing is an etch process, the backside shield 102 may increase the etch amount at the peripheral edge. On the other hand, when a backside shield 102 is not used, the abundance of available chemistry for processing is decreased as the processing beam scans off of the edge of the substrate 100 because there is no object to scatter the available chemistry back to the substrate 100. The efficacy of using a backside shield as a method of controlling the etch edge effect for PPE applications is illustrated in the plot of FIG. 2.

FIG. 2 is a plot 200 of etch amount of a polysilicon film at various radial locations from the center of a substrate for embodiments using a backside shield and embodiments without a backside shield at different scan speeds of the etch beam. Line C1 is an embodiment with a backside shield at a scan speed of 15 cm/s. Line C2 is an embodiment with no backside shield at a scan speed of 15 cm/s. Line C3 is an embodiment with no backside shield at a scan speed of 100 cm/s. For the majority of the radial locations from the center of the substrate, the etch amount is uniform for the different cases. Once the etch beam reaches the edge of the substrate (the radial locations further from the center is shown in a circled region 202 of the plot 200), the etch edge effect and the contrasting behavior of embodiments with and without a backside shield can be observed in the plot 200.

For example, in the circled region 202, both embodiments with the substrate and no backside shield have decreased poly etch amounts at the edge of the respective substrates (regardless of which scan speed of the etch beam was used (15 cm/s or 100 cm/s)). However, the embodiment with a backside shield mounted around the substrate has over-etched at the edge of the substrate, which implies the edge etch effect may be controlled through the implementation of a backside shield. Various embodiments of the backside shield which may be used to control the etch edge effect are illustrated in FIGS. 3A-3B, 4A-4B, 5A-5B, and FIG. 6.

In an embodiment, the etch edge effect on the substrate 100 may be controlled through the selection of the material comprising a backside shield 302, such as the aerial view of the backside shield 302 of non-porous material of FIG. 3A. In the diagram of FIG. 3A, the backside shield 302 is disposed around the substrate 100 and may comprise any material that is non-porous, or does not allow etching gas to pass through. For example, in an embodiment, the backside shield 302 may be the same material as the substrate 100, such as silicon. In other embodiments, the backside shield 302 comprises any material that consumes the reactant gas at a similar rate as the material being etched on the substrate 100.

Still referring to FIG. 3A, as a processing beam moves off of the surface of the substrate 100, the processing beam encounters the backside shield 302 which may scatter the available chemistry back to the edge of the substrate 100 to aid in processing and thus, control the etch edge effect. The behavior of the available chemistry for processing the substrate 100 with the backside shield 302 of non-porous material is illustrated in FIG. 3B.

FIG. 3B is a cross-sectional view of the backside shield 302 of non-porous material and the substrate 100. In an embodiment, when the backside shield 302 is non-porous to the impinging plasma, available processing chemistry may scatter off of both the surfaces of the substrate 100 and the backside shield 302 as schematically represented by a spreading cone 304. For example, as shown by the arrow 306, a particle may scatters off of the backside shield 302 and then participate in further processing at the edge of the substrate 100 resulting in the increased etch rate at the edge of the substrate 100.

Accordingly, in various embodiments, the etch edge effect may be controlled by choosing appropriate composition material for the backside shield 302 so as to reflect back the available processing chemistry at different rates to help with processing the substrate 100. For example, different etch edge effects may result when the substrate 100 is composed of different materials. Due to the varying etch edge effects at the edge of the substrate 100, different materials might be needed for the backside shield 302. The porous of the materials towards the impinging plasma flume could be varied in different embodiments. There are scenarios where a material is needed that reflects a lot of the available processing chemistry. This is particularly the case for designs with a large under-etch at the edge of the substrate 100.

In contrast, in conventional designs, no backside shield 302 is used. In such designs, the chemistry from the processing beam that scans off the edge of the substrate 100 is sucked out through the vacuum system and is not available for any etching of the edge of the substrate 100.

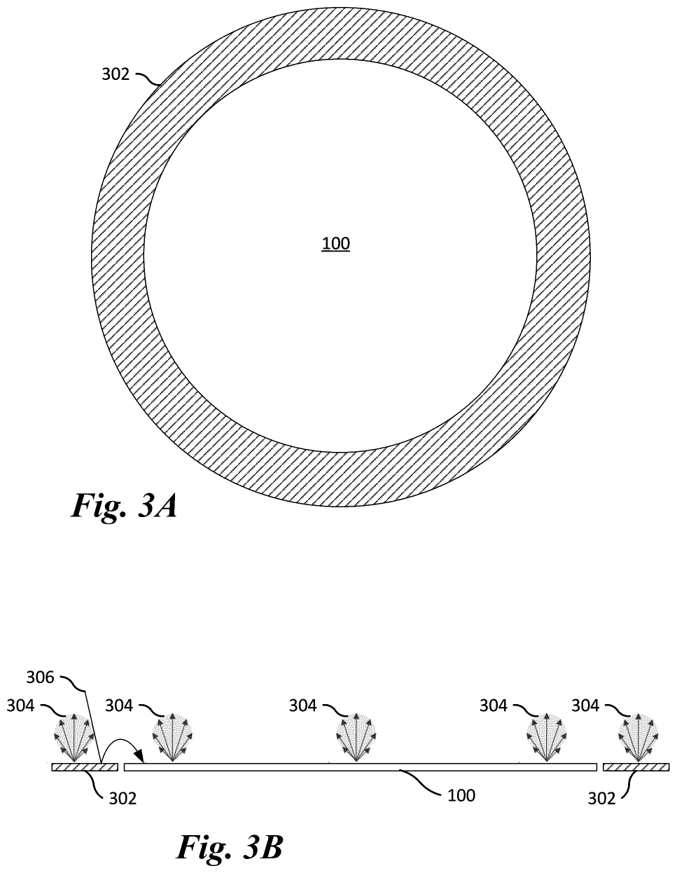

Other embodiments may use different materials for the backside shield to control the etch edge effect, such as the embodiment illustrated in FIG. 4A.

In another embodiment, the etch edge effect on the substrate 100 may be controlled through the selection of the material comprising a backside shield 402, such as the aerial view of the backside shield 402 of porous material illustrated in FIG. 4A. In the diagram of FIG. 4A, the backside shield 402 is disposed around the substrate 100 and may comprise any material that is porous, or allows etching gas to pass through. For example, in an embodiment, the backside shield 402 may be some form of perforated ceramic, such as yttrium oxide (Y₂O₃), or some other material that consumes the reactant gas at a similar rate as the material of the substrate 100. In various embodiments, the backside shield 402 may comprise a material machined to be partially open/transparent to the etching gas. For example, the machining of the backside shield 402 may be holes, slots, angled holes, angled slots, or etcetera (where the angles may be in the plane of the substrate 100 or transverse to the plane of the substrate 100). The behavior of the available chemistry for processing the substrate 100 with the backside shield 402 of porous material (or of material machined to be partially open/transparent) is illustrated in FIG. 4B.

FIG. 4B is a cross-sectional view of the backside shield 402 of porous material and the substrate 100. In an embodiment, when the backside shield 402 is porous to the plasma plume, available processing chemistry may scatter off of the material of the backside shield 402 along a spreading cone 404 when the available chemistry encounters the material of the backside shield 402.

On the other hand, when the available chemistry does not encounter the material of the backside shield 402, the available processing chemistry of the processing beam may pass through the porous backside shield 402, such as along a path 406. For example, a particle from the available processing chemistry may follow the path 406, where the particle passes through the backside shield 402. Particles of the available chemistry that pass through the backside shield 402 do not aid in processing the edge of the substrate 100. As a result, the quantity of available chemistry scattered back to the substrate 100 may be controlled by varying the porosity of the backside shield 402 to the plasma plume. Thus, the etch edge effect may be further controlled by choosing the material of the backside shield, such as using porous material like the embodiment of the backside shield 402 illustrated in FIG. 4B.

In an embodiment using a porous material as the backside shield 402, some available chemistry is allowed to pass through the backside shield 402, while some other is allowed to scatter back to the substrate 100 to ameliorate the etch edge effect. The ratio of scattered to pass through of the available chemistry may be adjusted by adjusting the porosity of the backside shield 402 to the plasma plume so as to achieve uniform processing of the substrate 100 and to control the etch edge effect.

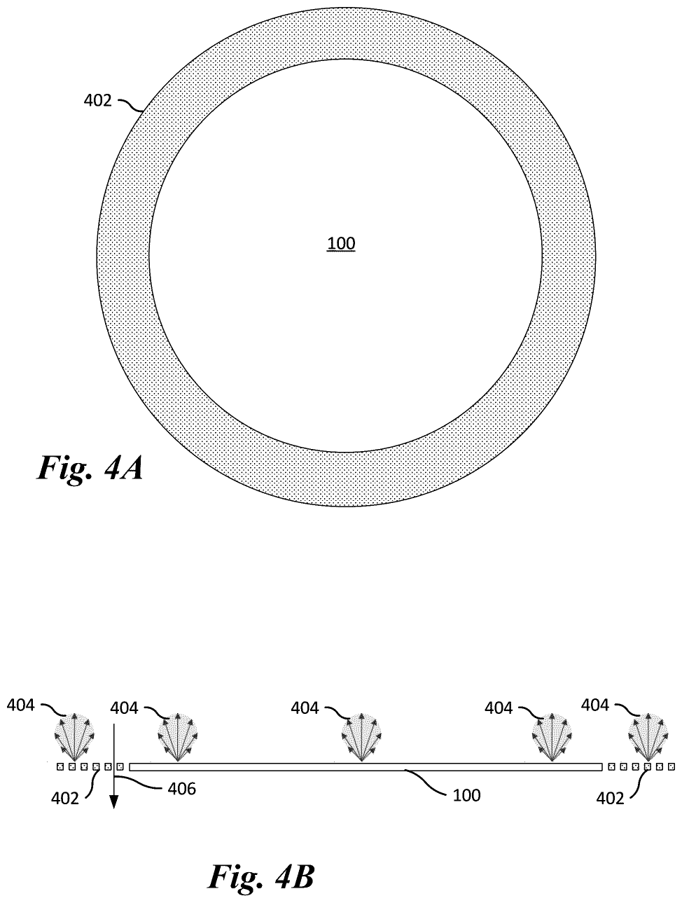

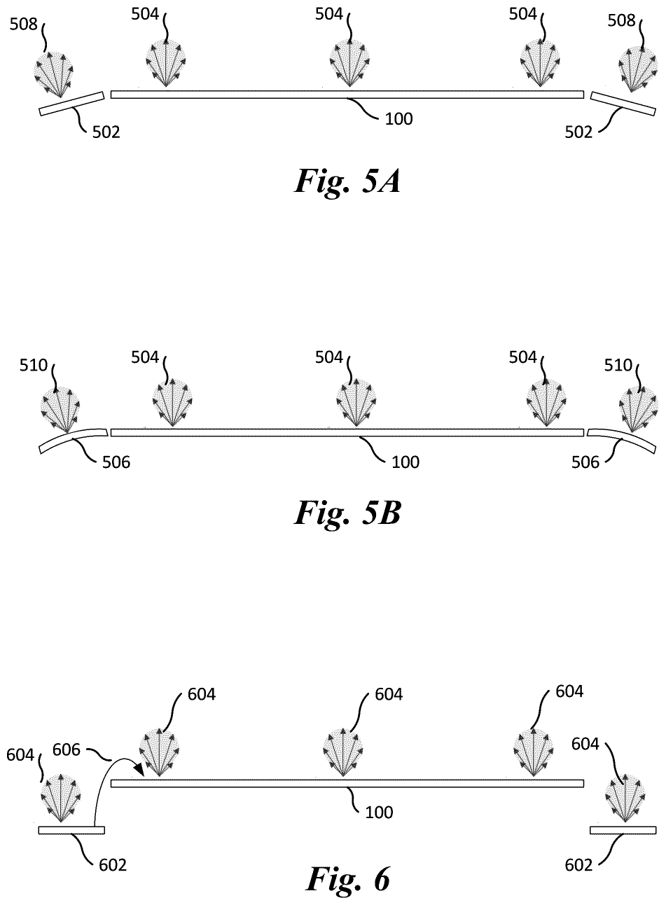

Various other embodiments may control the etch edge effect using a backside shield by configuring positional settings of the backside shield relative to the substrate 100. For example, FIGS. 5A-5B illustrate embodiments where the exposed major surface of the backside shield is angled relative to the substrate, and FIG. 6 illustrates an embodiment where the backside shield is recessed in height from the substrate. The embodiments of FIGS. 5A-5B configure an angle of the backside shield to control the etch edge effect, and the embodiment of FIG. 6 configures a height relative to the substrate to control the etch edge effect.

FIGS. 5A-5B illustrate embodiments where a backside shield is sloped to control the etch edge effect. In a sloped implementation of the backside shield, impinging particles of the available chemistry of the processing beam on the backside shield from the edge of the processing beam furthest from the substrate 100 may be reflected away from the substrate 100, while impinging particles of the available chemistry of the processing beam on the backside shield from the portion of the processing beam closer to the substrate 100 may be reflected back towards the substrate 100.

FIG. 5A illustrates a cross-sectional view of an embodiment of a backside shield 502 that is sloped, and where the entire backside shield 502 is disposed around the substrate 100 at an angle. FIG. 5B illustrates a cross-sectional view of an embodiment of a backside shield 506 that is sloped, and where the portion of the backside shield 506 near the substrate 100 is initially level to the substrate 100 and angles down further away from the substrate 100.

Referring to FIG. 5A, the backside shield 502 is angled away from the substrate 100 such that the scattering of available chemistry from the processing beam off of the backside shield 502 may be controlled. The angle of the backside shield 502 may control the quantity of the available chemistry scattered back to the substrate 100 to aid in processing the edge. For example, the edge of the substrate 100 will be etched significantly less when an angle of the backside shield 502 with the substrate 100 is larger compared to a case when the angle of the backside shield 502 with the substrate 100 is less. As a result of the angle of the backside shield 502, available chemistry scatters in an angled spreading cone 508 away from the substrate 100 when the available chemistry scatters off of the backside shield 502. By scattering the available chemistry along the angled spreading cone 508 away from the substrate 100, the amount of available chemistry that scatters back to the edge of the substrate 100 is decreased.

In other embodiments, the backside shield 502 may be angled up towards the substrate 100 to control the etch edge effect. In embodiments where the backside shield 502 is angled up towards the substrate 100, the amount of available chemistry scattered back to the edge of the substrate 100 is increased rather than decreased.

FIG. 5B is a cross-sectional view of an embodiment of a backside shield 506 that gradually slopes away from the substrate 100. In the gradually sloped embodiment of FIG. 5B, particles of the available chemistry may scatter on the substrate 100 along a spreading cone 504. But, as the processing beam scans over the substrate 100 and encounters the backside shield 506, the first portion of the backside shield 506 encountered by the available chemistry scatters back to the substrate 100 as described in previous embodiments (in other words, the amount of available chemistry for processing is increased in comparison to embodiments without a backside shield), and the amount of available chemistry reflected back to the edge of the substrate 100 decreases as the processing beam scans over the portion of the backside shield 506 sloping down away from the substrate 100.

When the processing beam scans over the sloping region of the backside shield 506, the available chemistry scatters in a sloped spreading cone 510 away from the substrate 100 and thus, the amount of available chemistry for processing the substrate 100 at the edge is decreased. As a result, the gradually sloped embodiment of the backside shield 506 may be used to control the etch edge effect. The etch edge effect may be further controlled by varying the sloping of the backside shield 506, such as by continuously varying the angle of the backside shield 506 as the radial distance from the center of the substrate 100 increases.

Though FIG. 5B illustrates an embodiment where the backside shield 506 eventually slopes down away from the substrate 100, other embodiments where the backside shield 506 slopes upwards towards the substrate 100 are also possible. In an embodiment with an upwards sloped backside shield, the amount of available chemistry scattered back to the substrate 100 is increased and the processing at the edge of the substrate 100 would be increased. The amount of etch edge effect determines the ideal configuration of the backside shield 506.

FIG. 6 illustrates an embodiment of a backside shield 602 that may be used to control the etch edge effect on the substrate 100. In the embodiment illustrated in FIG. 6, the backside shield 602 is offset in height from the substrate 100. By offsetting the backside shield 602 from the substrate 100, the amount of etch at the edge of the substrate 100 may be controlled. For example, by increasing the height difference between the backside shield 602 and the substrate 100, the amount of processing at the edge of the substrate 100 may be reduced because the amount of available chemistry reflected back to the substrate 100 is reduced. On the other hand, by decreasing the height difference between the backside shield 602 and the substrate 100, the amount of processing at the edge of the substrate may be increased because the amount of available chemistry reflected back to the substrate 100 is increased.

In an embodiment with a height difference between the backside shield 602 and the substrate 100, particles of the available chemistry from the processing beam may interact with the surfaces of the substrate 100 and the backside shield 602 as an impact spreading cone 604. And a particle of the available chemistry from the impact spreading cone 604 may follow a path 606 to process the edge of the substrate 100. A larger height difference (recess difference) between the substrate 100 and the backside shield 602 correlates to decreased available chemistry for processing the edge of the substrate 100.

In an embodiment, the backside shield 602 may comprise a plurality of concentric rings that are individually configurable to be placed at a different depth relative to the surface of the substrate 100. Thus, the depth of the radially furthest location on the backside shield 602 can be configured to be significantly larger (positive or negative) than the depth of a location on the backside shield 602 closest to the substrate 100.

Other embodiments may use mixtures of the embodiments of the backside shield for controlling the etch edge effect illustrated and described in the detailed descriptions of FIGS. 3A-3B, 4A-4B, 5A-5B, and 6. For example, an embodiment may control the etch edge effect by using a backside shield of porous material, having a recessed height from the substrate 100, and sloped at an angle relative to the substrate 100. Other mixtures of the various embodiment backside shields above may also be used, such as embodiments using a backside shield sloped towards the substrate 100 rather than away. A method for controlling the etch edge effect using a backside shield is described using FIG. 7.

A method of controlling the etch edge effect in a partial plasma etch application using a backside shield mounted around the substrate is illustrated as the flowchart in FIG. 7. The method 700 may begin in box 702. In box 702, a substrate is loaded in a processing chamber along with a backside shield mounted around the substrate.

After loading the substrate in the processing chamber along with the backside shield, the method 700 proceeds to box 704. In box 704, the method 700 configures a processing parameter of the backside shield according to a calibration specific to a process recipe (or according to multiple calibrations specific to multiple process recipes). In various embodiments, the processing parameter may comprise height and angle settings for the backside shield to control the etch edge effect. For example, the height setting may control the offset in height between the backside shield and the substrate, such as the embodiment illustrated in FIG. 6. As another example, the angle settings may be the angle of the backside shield compared to the substrate, such as an embodiment illustrated in FIGS. 5A-5B.

In other embodiments, the processing parameter for the backside shield may comprise both height and angle settings to offset the backside shield in height and angle from the substrate. In even further embodiments, the processing parameter may further include the material the backside shield comprises, such as a perforated ceramic material.

In box 706, the method 700 generates, based on the process recipe, a plasma at a plasma source. In various embodiments, the plasma source may be the plasma source 160 of FIG. 1A. And after generating the plasma, the method 700 proceeds to box 708. In box 708, the method 700 directs, based on the process recipe, the plasma into the processing chamber and towards the outer surface of the substrate and the backside shield using a nozzle. In an embodiment, the nozzle may be the processing nozzle 150 of FIG. 1A.

Once the plasma has been directed into the processing chamber towards the outer surface of the substrate and the backside shield using the nozzle, the method 700 may proceed to box 710. In box 710, the method 700 processes the substrate by exposing the substrate and the backside shield to the plasma based on the process recipe. For example, the process recipe may be an etch process, and through the configuration settings, the etch edge effect at the edge of the substrate may be controlled so the process recipe does not under etch the peripheral edge.

In another embodiment, the method 700 may further comprise steps for scanning and adjusting the set of parameters of the backside shield based on a scan of the edge of the substrate during processing. In other words, while the substrate is processed using the process recipe, the measurement device may be used to monitor and adjust the set of parameters of the backside shield based on an algorithm that determines if the process will over etch or under etch the edge of the substrate. For example, if the algorithm determines under etch of the edge of the substrate may occur at the end of the process recipe, the set of parameters of the backside shield may be adjusted to increase the amount of etch at the edge of the substrate, such as by lowering the porosity of the backside shield (e.g., in FIG. 4B), lowering the angle of the backside shield (e.g., in FIGS. 5A-5B) raising the height of the backside shield to be closer to level with the substrate (e.g., in FIG. 6). A method for determining the calibration of the set of parameters of the backside shield is described using FIG. 8.

A method of calibrating a system for processing a substrate including a backside shield is illustrated as the flowchart in FIG. 8. The calibration method 800 may begin in box 802. In box 802, a substrate is loaded in a processing chamber along with a backside shield mounted around the substrate. The calibration method 800 processes the substrate according to a process recipe to form a processed substrate in box 804. In an embodiment, the process recipe may be for an etch process, such as a partial plasma etch (PPE) application.

After processing the substrate according to the process recipe, the calibration method 800 proceeds to box 806. In box 806, the calibration method 800 scans an edge of the processed substrate using a measurement device. In an embodiment, the measurement device may be the measurement device 170 of the plasma processing system 10 of FIG. 1A. Once the edge of the processed substrate has been scanned, the calibration method 800 proceeds to box 808.

In box 808, the calibration method 800 determines a process amount of the edge based on the scan of the processed substrate. For example, in an embodiment where the process recipe is an etch recipe, the process amount may be an etch amount. In other embodiments, the process recipe may be a deposition recipe, and the process amount may be a deposition amount at the edge of the processed substrate. The determination of the process amount may be done by any process capable of determining the process amount from a scan of the edge of the processed substrate. Once the process amount is determined, the calibration method 800 determines a set of processing parameters for the backside shield for the specific process recipe based on the process amount.

For example, in the case the process amount is an etch amount and is consistent with over-etch, the set of processing parameters may be configured such that the backside shield reduces the etch amount at the edge of the substrate, such as angling the backside shield (like the embodiment illustrated in FIGS. 5A-5B), or recessing the backside shield relative to the substrate to create a height difference (like the embodiment illustrated in FIG. 6). In other embodiments, different combinations of the embodiments of the backside shields illustrated in FIGS. 3A-3B, 4A-4B, 5A-5B, and 6 may be used to control the etch edge effect, such as an embodiment using a backside shield of porous material angled away from the substrate, and recessed in height from the substrate.

Accordingly, embodiments of the disclosure are able to improve across wafer uniformity during partial plasma etch process without changing the plasma properties, scanning, and other process parameters. Embodiments of this disclosure advantageously achieve this by changing the parameters relating to the features of the backside shield. Example embodiments of the invention are described below. Other embodiments can also be understood from the entirety of the specification as well as the claims filed herein.

Example 1. A method for controlling an etch edge effect in a partial plasma etch process includes loading a substrate in a processing chamber with a backside shield disposed around the substrate, and configuring the backside shield according to a calibration specific to one or more process recipes. The method further includes generating, based on the process recipe, a plasma at a plasma source, and directing, based on the process recipe, the plasma into the processing chamber and towards outer surfaces of the substrate and the backside shield using a nozzle. And the method further includes processing the substrate by exposing the substrate and the backside shield to the plasma based on the one or more process recipes.

Example 2. The method of example 1, further includes moving the substrate and the backside shield relative to the nozzle with a measurement device.

Example 3. The method of one of examples 1 or 2, where the one or more process recipes include a partial plasma etch process for burnishing a layer of the substrate.

Example 4. The method of one of examples 1 to 3, where the backside shield includes a plurality of arcs disposed around the substrate.

Example 5. The method of one of examples 1 to 4, where the backside shield includes a perforated ceramic material.

Example 6. The method of one of examples 1 to 5, where the backside shield includes the same material as the substrate.

Example 7. The method of one of examples 1 to 6, further includes adjusting the backside shield based on the one or more process recipes.

Example 8. The method of one of examples 1 to 7, where adjusting the backside shield includes adjusting the outer surface of the backside shield to be inclined at an angle with the outer surface of the substrate.

Example 9. The method of one of examples 1 to 8, where adjusting the backside shield includes adjusting the outer surface of the backside shield to be at a different height relative to the outer surface of the substrate.

Example 10. The method of one of examples 1 to 9, where the backside shield includes a plurality of concentric regions, where adjusting the backside shield includes adjusting each of the plurality of concentric regions to have a different height relative to the outer surface of the substrate.

Example 11. A system includes a measurement device, a plasma source, a processing chamber, the plasma source being coupled to the processing chamber through a nozzle, the nozzle configured to emit a processing beam into the processing chamber, and a substrate holder disposed in the processing chamber and being configured to support a substrate. The system further includes a backside shield disposed in the processing chamber and being configured to laterally surround an edge of the substrate, a stage supporting the substrate holder and being disposed in the processing chamber. And the system further includes a controller coupled to the stage, and a memory storing instructions to be executed by the controller. The instructions when executed cause the controller to configure the backside shield according to a calibration specific to one or more process recipes, generate, based on the one or more process recipes, a plasma at a plasma source, direct, based on the one or more process recipes, the plasma into the processing chamber and towards outer surfaces of the substrate and the backside shield using the nozzle, and process the substrate according to the one or more process recipes by scanning the substrate with the processing beam to expose different regions of the substrate to the processing beam.

Example 12. The system of example 11, where the instructions when executed further cause the controller to scan an edge of the substrate with the measurement device during the processing.

Example 13. The system of one of examples 11 or 12, where the backside shield includes a plurality of arcs disposed around the substrate.

Example 14. The system of one of examples 11 to 13, where the backside shield includes a perforated ceramic material.

Example 15. The system of one of examples 11 to 14, where the backside shield includes a semiconductor material.

Example 16. The system of one of examples 11 to 15, where the instructions when executed further cause the controller to adjust the outer surface of the backside shield to be inclined at an angle with the outer surface of the substrate.

Example 17. The system of one of examples 11 to 16, where the instructions when executed further cause the controller to adjust the outer surface of the backside shield to be at a different height relative to the outer surface of the substrate.

Example 18. The system of one of examples 11 to 17, where the backside shield includes a plurality of concentric regions, and where the instructions when executed further cause the controller to adjust each of the plurality of concentric regions to have a different height relative to the outer surface of the substrate.

Example 19. A calibration method includes loading a first substrate in a processing chamber with a backside shield disposed around the first substrate, and generating, based on one or more process recipes, a plasma at a plasma source. The calibration method further includes directing, based on the one or more process recipes, the plasma into the processing chamber and towards outer surfaces of the first substrate and the backside shield using a nozzle, and processing the first substrate, based on the one or more process recipes, by exposing the first substrate and the backside shield to the plasma to form a processed first substrate. And the calibration method further includes scanning an edge of the processed first substrate using a measurement device, determining a process amount of the edge based on the scanning, and determining a configuration of the backside shield for the one or more process recipes based on the process amount.

Example 20. The method of example 19, further includes loading a second substrate in the processing chamber with the backside shield disposed around the second substrate, configuring the backside shield according to the configuration determined for the one or more process recipes. The method further includes directing, based on the one or more process recipes, the plasma into the processing chamber and towards outer surfaces of the second substrate and the backside shield using the nozzle, and processing the second substrate by exposing the second substrate and the backside shield to the plasma based on the one or more process recipes.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for controlling an etch edge effect in a partial plasma etch process, the method comprising:
loading a substrate in a processing chamber with a backside shield disposed around the substrate;
configuring the backside shield according to a calibration specific to one or more process recipes;
generating, based on the process recipe, a plasma at a plasma source;
directing, based on the process recipe, the plasma into the processing chamber and towards outer surfaces of the substrate and the backside shield using a nozzle; and
processing the substrate by exposing the substrate and the backside shield to the plasma based on the one or more process recipes.

2. The method of claim 1, further comprising:
moving the substrate and the backside shield relative to the nozzle with a measurement device.

3. The method of claim 1, wherein the one or more process recipes comprise a partial plasma etch process for burnishing a layer of the substrate.

4. The method of claim 1, wherein the backside shield comprises a plurality of arcs disposed around the substrate.

5. The method of claim 1, wherein the backside shield comprises a perforated ceramic material.

6. The method of claim 1, wherein the backside shield comprises the same material as the substrate.

7. The method of claim 1, further comprising adjusting the backside shield based on the one or more process recipes.

8. The method of claim 7, wherein adjusting the backside shield comprises adjusting the outer surface of the backside shield to be inclined at an angle with the outer surface of the substrate.

9. The method of claim 7, wherein adjusting the backside shield comprises adjusting the outer surface of the backside shield to be at a different height relative to the outer surface of the substrate.

10. The method of claim 1, wherein the backside shield comprises a plurality of concentric regions, wherein adjusting the backside shield comprises adjusting each of the plurality of concentric regions to have a different height relative to the outer surface of the substrate.

11. A system comprising:
a measurement device;
a plasma source;
a processing chamber, the plasma source being coupled to the processing chamber through a nozzle, the nozzle configured to emit a processing beam into the processing chamber;
a substrate holder disposed in the processing chamber and being configured to support a substrate;
a backside shield disposed in the processing chamber and being configured to laterally surround an edge of the substrate;
a stage supporting the substrate holder and being disposed in the processing chamber; and
a controller coupled to the stage, and a memory storing instructions to be executed by the controller, the instructions when executed cause the controller to:
configure the backside shield according to a calibration specific to one or more process recipes,
generate, based on the one or more process recipes, a plasma at a plasma source,
direct, based on the one or more process recipes, the plasma into the processing chamber and towards outer surfaces of the substrate and the backside shield using the nozzle, and
process the substrate according to the one or more process recipes by scanning the substrate with the processing beam to expose different regions of the substrate to the processing beam.

12. The system of claim 11, wherein the instructions when executed further cause the controller to:
scan an edge of the substrate with the measurement device during the processing.

13. The system of claim 11, wherein the backside shield comprises a plurality of arcs disposed around the substrate.

14. The system of claim 11, wherein the backside shield comprises a perforated ceramic material.

15. The system of claim 11, wherein the backside shield comprises a semiconductor material.

16. The system of claim 11, wherein the instructions when executed further cause the controller to adjust the outer surface of the backside shield to be inclined at an angle with the outer surface of the substrate.

17. The system of claim 11, wherein the instructions when executed further cause the controller to adjust the outer surface of the backside shield to be at a different height relative to the outer surface of the substrate.

18. The system of claim 11, wherein the backside shield comprises a plurality of concentric regions, and wherein the instructions when executed further cause the controller to adjust each of the plurality of concentric regions to have a different height relative to the outer surface of the substrate.

19. A calibration method comprising:
loading a first substrate in a processing chamber with a backside shield disposed around the first substrate;
generating, based on one or more process recipes, a plasma at a plasma source;
directing, based on the one or more process recipes, the plasma into the processing chamber and towards outer surfaces of the first substrate and the backside shield using a nozzle;
processing the first substrate, based on the one or more process recipes, by exposing the first substrate and the backside shield to the plasma to form a processed first substrate;
scanning an edge of the processed first substrate using a measurement device;
determining a process amount of the edge based on the scanning; and
determining a configuration of the backside shield for the one or more process recipes based on the process amount.

20. The method of claim 19, further comprising:
loading a second substrate in the processing chamber with the backside shield disposed around the second substrate;
configuring the backside shield according to the configuration determined for the one or more process recipes;
directing, based on the one or more process recipes, the plasma into the processing chamber and towards outer surfaces of the second substrate and the backside shield using the nozzle; and
processing the second substrate by exposing the second substrate and the backside shield to the plasma based on the one or more process recipes.
